(19) United States
(12) Patent Application Publication
(10) Pub. No.: US 2006/0240590 A1
(43) Pub. Date: Oct. 26, 2006

(54) Controlled synthesis of nanowires, nanodiscs, and nanostructured materials using liquid crystalline templates

(75) Inventors: Triantafillos J. Mountziaris, Williamsville, NY (US); Paschalis Alexandridis, E. Amherst, NY (US); Georgios N. Karanikolos, Minneapolis, MN (US)

Correspondence Address: NIXON PEABODY LLP - PATENT GROUP, CLINTON SQUARE, P.O. BOX 31051, ROCHESTER, NY, 14603-1051, US

(73) Assignee: The Research Foundation of State University of New York, Amherst, NY (US)

(21) Appl. No.: 11/270,692

(22) Filed: Nov. 9, 2005

Related U.S. Application Data
(60) Provisional application No. 60/626,126, filed on Nov. 9, 2004.

(51) Int. Cl. H01L 51/40

(52) U.S. Cl. 438/99; 977/700

(57) ABSTRACT

A process for synthesizing nanostructures involving providing a first reactant, forming a liquid crystalline template containing the first reactant and contacting the template with a gas phase composed of a second reactant under conditions effective to form nanostructures is disclosed. A method of making a liquid crystalline template by combining and allowing to react a block copolymer, a polar continuous phase material, and a dispersed nonpolar phase material under conditions effective to form the liquid crystalline template is also disclosed.

This application claims the benefit of U.S. Provisional Patent Application Ser. No. 60/626,126, filed Nov. 9, 2004, which is hereby incorporated by reference in its entirety.

### FIELD OF THE INVENTION

The present invention is directed to a process for synthesizing nanowires, nanodiscs, and nanostructures using liquid crystalline templates and for synthesizing a liquid crystalline template used in such process.

### BACKGROUND OF THE INVENTION

A great variety of techniques are being used for the synthesis of nanoparticles of inorganic compounds. Most of these techniques suffer from lack of precision in controlling particle size and properties. The current state of the art in the synthesis of semiconductor nanocrystals involves the use of high temperature batch reactors. This process uses a hot coordinating solvent, such as hexadecylamine and trioctyl-phosphine, in which the reactants are injected with a syringe. Particles grow as a function of time and samples are taken at specific times to obtain populations of a certain average size. It is difficult to precisely control particle size distribution in such reactors and very difficult to isolate particles with a specific, pre-determined particle size. Using this approach, post-processing and functionalization requires many additional steps that can compromise the quality of the particles. Further, the technique cannot be scaled-up easily for industrial production.

Semiconductor nanocrystals are currently under intense investigation due to their unique, size-dependent optical and electronic properties that differ significantly from those observed in the bulk material (Rossetti et al., “Quantum Size Effects in the Redox Potentials, Resonance Ramam Spectra, and Electronic CdS Crystallites in Aqueous Solution,” J. Chem. Phys. 79(2):1086-1088 (1983); Fendler, J. H., “Self-Assembled Nanostructured Materials,” Chem. Mater. 8(8):1616-1624 (1996); Murray et al., “Synthesis and Characterization of Monodisperse Nanocrystals and Close-Packed Nanocrystal Assemblies,” Annu. Rev. Mater. Sci. 30:545-610 (2000); Alivisatos, A. P., “Semiconductor Clusters, Nanocrystals, and Quantum Dots,” Science 271:933-937 (1996)). When at least one dimension of the nanocrystals becomes smaller than the corresponding de Broglie wavelength or Bohr radius (mean separation of an optically excited electron-hole pair), quantum confinement phenomena take place that can change the nanocrystal properties (Fendler, J. H., “Self-Assembled Nanostructured Materials,” Chem. Mater. 8(8):1616-1624 (1996)). Nanocrystals confining electron-hole pairs in zero dimensions (quantum dots) can exhibit size-dependent luminescence, broad excitation by any wavelength smaller than the emission wavelength, high brightness, high sensitivity, and high photostability (Murray et al., “Synthesis and Characterization of Monodisperse Nanocrystals and Close-Packed Nanocrystal Assemblies,” Annu. Rev. Mater. Sci. 30:545-610 (2000)). Such properties make them useful for a variety of applications, including light emitting diodes, photodetectors and photovoltaics (Alivisatos, A. P., “Semiconductor Clusters, Nanocrystals, and Quantum Dots,” Science 271:933-937 (1996)), and as fluorescent biological labels (Michalet et al., “Properties of Fluorescent Semiconductor Nanocrystals and Their Application to Biological Labeling,” Single Mol. 2(4):261-276 (2001)). On the other hand, semiconductor nanowires and nanorods that confine electron-hole pairs in one dimension have been attracting attention for fundamental studies in mesoscopic physics and for their potential applications as interconnects and functional units in nanoelectronics (Xia et al., “One-Dimensional Nanostructures: Synthesis, Characterization, and Applications,” Adv. Mater. 15(5):353-389 (2003)).

The most common synthesis route for II-VI nanocrystals involves reactions between organometallic compounds in a trioctylphosphine (“TOP”)/trioctylphosphine oxide (“TOPO”) and/or hexadecylamine (“HAD”) coordination solvent carried out in small batch reactors operating at ˜300° C. CdSe and CdS quantum dots have been the most common materials grown by this technique (Murray et al., “Synthesis and Characterization of Nearly Monodisperse CdE (E=sulfur, selenium, tellurium) Semiconductor Nanocrystallites,” J. Am. Chem. Soc. 115(19):8706-8715 (1993)). Luminescent ZnSe nanocrystals exhibiting high quantum yield (Hines et al., “Bright UV-Blue Luminescent Colloidal ZnSe Nanocrystals,” J. Phys. Chem. B. 102(10):3655-3657 (1998); Revaprasadu et al., “Single-Source Molecular Precursors for the Deposition of Zinc Selenide Quantum Dots,” J. Mater. Chem. 8:1885-1888 (1998)) and (Zn,Mn)Se diluted magnetic nanocrystals (Norris et al., “High-Quality Manganese-Doped ZnSe Nanocrystals,” Nano Lett. 1(1):3-7 (2001)) have also been grown. To grow monodisperse nanocrystal populations the requirements include instantaneous injection and mixing of the reactants, uniform nucleation over the entire mass of the solvent, and perfect mixing during the entire process. Such conditions are difficult to achieve and selective precipitation techniques are used after synthesis to narrow down the size distribution of the nanocrystals (Murray et al., “Synthesis and Characterization of Monodisperse Nanocrystals and Close-Packed Nanocrystal Assemblies,” Annu. Rev. Mater. Sci. 30:545-610 (2000)). Other reported techniques for growing ZnSe nanocrystals include arrested precipitation (Chestnoy et al., “Higher Excited Electronic States in Clusters of ZnSe, CdSe, and ZnS: Spin-Orbit, Vibronic, and Relaxation Phenomena,” J. Chem. Phys. 85(4):2237-2242 (1986)), sol-gel processing (Li et al., “Preparation and Optical Properties of Sol-Gel Derived ZnSe Crystallites Doped in Glass Films,” J. Appl. Phys. 75(8):4276-4278 (1994)), sono-chemical processing (Zhu et al., “General Sonochemical Method for the Preparation of Nanophasic Selenides: Synthesis of ZnSe Nanoparticles,” Chem. Mater. 12(1):73-78 (2000)), growth in reverse micelles (Quinlan et al., “Reverse Micelle Synthesis and Characterization of ZnSe Nanoparticles,” Langmuir 16(8):4049-4051 (2000)), and vapor-phase synthesis (Sarigiannis et al., “Characterization of Vapor-Phase-Grown ZnSe Nanoparticles,” Appl. Phys. Lett. 80(21):4024-4026 (2002)).

The use of a template is typically required for growing monodisperse particle populations. Microemulsion templates have been employed for such a task. Control of particle microstructure has been achieved by colloidal crystallization in aqueous droplets suspended on the surface of a fluorinated oil (Velev et al., “A Class of Microstructured Particles Through Colloidal Crystallization,” Science 287:2240-2243 (2000)). Monodisperse populations of Si quantum dots, with surfaces passivated by an organic monolayer, were grown by thermally degrading diphenysilane in supercritical octanol (Holmes et al., “Highly Luminescent Silicon Nanocrystals with Discrete Optical Transitions,” J. Am. Chem. Soc. 123(16):3743-3748 (2001)). ZnSe nanocrystals were grown in bis-2-ethylhexylsulphosuccinate sodium salt (AOT) reverse micelles by reacting zinc perchlorate hexahydrate and sodium selenide (Quinlan et al., “Reverse Micelle Synthesis and Characterization of ZnSe Nanoparticles,” Langmuir 16(8):4049-4051 (2000)). Under ideal conditions, reverse micelles could function as identical nanoreactors, thus providing a template for precise control of particle size. In practice, the fast dynamics of droplet coalescence in water-in-oil microemulsions lead to the formation of droplet clusters and polydisperse particle populations (Zhao et al., “Preparation of CdS Nanoparticles in Salt-Induced Block Copolymer Micelles,” Langmuir 17(26):8428-8433 (2001)).

Highly luminescent ZnSe quantum dots have been grown from diethylzinc and Se powder in a coordinating solvent of tri-η-octylphosphine (TOP) and hexadecylamine (HDA) at 270° C. (Hines et al., “Bright UV-Blue Luminescent Colloidal ZnSe Nanocrystals,” J. Phys. Chem. B 102(19):3655 (1998)). A single-source precursor has been used to grow ZnSe quantum dots in tri-η-octylphosphine oxide (TOPO) at 250° C. (Revaprasadu et al., “Single-Source Molecular Precursors for the Deposition of Zinc Selenide Quantum Dots,” J. Mater. Chem. 8(8):1885-1888 (1998)). Polymer capping agents have been used to encapsulate and stabilize ZnSe quantum dots grown from zinc chloride and sodium selenosulfate solutions at room temperature (Leppert et al., “Structural and Optical Characteristics of ZnSe Nanocrystals Synthesized in the Presence of a Polymer Capping Agent,” Mater. Sci. Eng. B 52(1):89-92 (1998); Kumbhojkar et al., “Quantum Confinement Effects in Chemically Grown, Stable ZnSe Nanoclusters,” Nanostruct. Mater. 10(2):117-129 (1998)). The as-grown quantum dot populations from the above techniques have a relatively wide size distribution that can be narrowed down by several post-processing steps including size-selective precipitation (Hines et al., “Bright UV-Blue Luminescent Colloidal ZnSe Nanocrystals,” J. Phys. Chem. B 102(19):3655 (1998)). In an effort to grow ZnSe quantum dots and obtain narrow size distributions by use of a template, reverse micelles have been employed Quinlan et al., “Reverse Micelle Synthesis and Characterization of ZnSe Nanoparticles,” Langmuir 16(8):4049-4051 (2000)), but the high rate of micelle-micelle coalescence (Alexandridis et al., “Thermodynamics of Droplet Clustering in Percolating AOT Water-in-Oil Microemulsions,” J. Phys. Chem. 99(20):8222-8232 (1995)) prevented a narrow focusing of the size distribution. Recently, one group has reported the growth of luminescent ZnSe quantum dots using a new microemulsion template that has slow droplet—droplet coalescence kinetics and thus allows the narrow focusing of the particle size distribution of the as-grown quantum dots by forming a single quantum dot per droplet (Karanikolos et al., “Synthesis and Size Control of Luminescent ZnSe Nanocrystals by a Microemulsion-Gas Contacting Technique,” Langmuir 20(3):550-553 (2004)).

Preparation of ZnSe nanowires and nanorods with diameters of several tens of nanometres has been reported in the literature by a variety of techniques, including metal organic chemical vapour deposition (MOCVD) using colloidal Ag particles as catalyst (Zhang et al., “Growth and Luminescence of Zinc-Blende-Structured ZnSe Nanowires by Metal-Organic Vapor Deposition,” Appl. Phys. Lett. 8(26)3:5533-5535 (2003)), solvothermal processing (Wang et al., “Synthesis and Characterization of MSe (M═Zn, Cd) Nanorods by a New Solvothermal Method,” Inorg. Chem. Commun. 2(3):83-85 (1999)), electrodeposition inside a porous alumina film (Kouklin et al., “Giant Photoresistivity and Optically Controlled Switching in Self-Assembled Nanowires,” Appl. Phys. Lett. 79(26):4423-4425 (2001)), laser ablation using Au as catalyst (Jiang et al., “Zinc Selenide Nanoribbons and Nanowires,” J. Phys. Chem. B 108(9):2784-2787 (2004)), a self-catalysed vapour-liquid-solid (VLS) method (Zhu et al., “Preparation and Photoluminescence of Single-Crystal Zinc Selenide Nanowires,” Chem. Phys. Lett. 377(3-4):367-370 (2003)), and a surfactant template method (Lv et al., “Growth and Characterization of Single-Crystal ZnSe Nanorods via Surfactant Soft-Template Method,” Solid State Commun. 130(3-4):241-245 (2004)).

The control of the shape and structure of nanoscale materials, like nanowires, focuses mostly on carbon nanotubes that are synthesized through a catalytic process employing metal (gold) nanoparticles as “seeds”. This technique has also been used for demonstration of the synthesis of semiconductor nanowires. However, a critical issue is the poor control over nanowire size and lack of an ability to grow more complex shapes, such as bi-continuous structures, honeycombs, and the like.

Thus, there is a need for developing techniques that enable precise control of the shape, size and orientation of these materials. A variety of techniques have been reported that utilize templates or surfactant-mediated growth for controlling the size and shape of meso- and nano-scale materials. Examples include the use of amphiphilic compounds as a template for the growth of zirconium oxide with a mesostructured framework (Wong et al., “Amphiphilic Templating of Mesostructured Zirconium Oxide,” Chem. Mater. 10(8):2067-2077 (1998)), the surfactant-mediated growth of monodisperse iron oxide nanoparticles (Teng et al., “Effects of Surfactants and Synthetic Conditions on the Sizes and Self-Assembly of Monodisperse Iron Oxide Nanoparticles,” J. Mater. Chem. 14(4):774-779 (2004)), the growth of colloidal crystals in aqueous droplets suspended in a fluorinated oil (Velev et al., “A Class of Microstructured Particles Through Colloidal Crystallization,” Science 287:2240-2243 (2000)), and the synthesis of Si quantum dots by thermally degrading diphenylsilane in supercritical octanol (Holmes et al., “Highly Luminescent Silicon Nanocrystals with Discrete Optical Transitions,” J. Am. Chem. Soc. 123(16):3743-3748 (2001)).

The present invention overcomes these deficiencies in the art by employing novel templates based on amphiphilic systems that enable precise control of size, structure, shape and composition of nanostructured materials.

### SUMMARY OF THE INVENTION

One aspect of the present invention relates to a process for synthesizing nanostructures. The process involves providing a first reactant, forming a liquid crystalline template containing the first reactant and contacting a gas phase made of a second reactant diluted in a carrier gas with the liquid crystalline template. The second reactant is then allowed to react with the first reactant under conditions effective to form nanostructures.

Another aspect of the present invention relates to a process of forming a liquid crystalline template. The process involves providing a block copolymer, providing a polar continuous phase material, providing a dispersed nonpolar phase material, and allowing the block copolymer, polar continuous phase material, and dispersed nonpolar phase material to come into contact with each other under conditions effective to form the liquid crystalline template.

### BRIEF DESCRIPTION OF THE DRAWINGS

FIG. 1 shows a partial ternary isothermal phase diagram of the EO₃₇PO₅₈EO₃₇-heptane-formamide system at room temperature.

FIG. 2 illustrates the mechanism of ZnSe nanowire growth inside the cylindrical self-assembled nanodomains of a PEO-PPO-PEO/heptane/formamide lyotropic liquid crystal.

FIGS. 3A-D are TEM images of ZnSe quantum dots. The scale bars correspond to 5 nm.

FIG. 4 illustrates room-temperature photoluminescence spectra of ZnSe quantum dots synthesized by liquid crystal templating. The inset is a schematic diagram of a ZnSe quantum dot encapsulated in a heptane-containing micelle.

FIGS. 5A-B are TEM images of ZnSe nanowires. The scale bars correspond to 10 nm.

FIG. 6 shows the X-ray diffraction pattern of ZnSe nanowires.

FIG. 7 illustrates room-temperature photoluminescence of ZnSe nanowires. The inset is a schematic of a ZnSe nanowire encapsulated in a heptane cylindrical nanodomain.

FIGS. 8A-E show TEM images from ZnSe nanodiscs.

FIG. 9 illustrates room-temperature photoluminescence from ZnSe nanodiscs synthesized in lamellar liquid crystals. The inset is a schematic diagram of a ZnSe nanodisc encapsulated in a heptane lamellar nanodomain.

### DETAILED DESCRIPTION OF THE INVENTION

The present invention relates to techniques for controlled synthesis of zero-, one-, and two-dimensional compound semiconductor nanostructures by using cubic, hexagonal, and lamellar lyotropic liquid crystals as templates, respectively. The liquid crystals are formed by self-assembly in a ternary system of a poly(ethylene oxide)-poly(propylene oxide)-poly(ethylene oxide) amphiphilic block copolymer as the surfactant, heptane as the non-polar dispersed phase, and formamide as the polar continuous phase. ZnSe quantum dots and nanowires with diameters smaller than 10 nm, as well as free-standing, disc-like quantum wells, were grown inside the spherical, cylindrical, and planar nanodomains, respectively, by reacting diethylzinc that was dissolved in the heptane domains with hydrogen selenide gas that was brought into contact with the liquid crystal in a sealed chamber at room temperature and atmospheric pressure. The shape and size of the resulting nanostructures can be manipulated by selecting the templating phase of the liquid crystal, the size of the dispersed nanodomains that is controlled by the composition of the template, and the concentration of diethylzinc in them.

The present invention employs liquid crystalline templates to achieve the controlled synthesis of nanowires by exposing the liquid crystals to a reactive gas inside a stainless steel chamber. This technology allows the synthesis of a variety of nanostructures of materials, such as compound semiconductors, oxides, magnetic semiconductors, with controllable optical, magnetic, and surface properties. Potential applications further include nanoelectronics, nanomagnetics, biomedical engineering, adaptive coatings, nanoscale honeycombed materials, high-efficiency adsorbents for gas separations, and novel catalysts.

The present invention further solves the challenging problem of simultaneously controlling size, shape, structure, and composition of nanoscale materials. It offers great flexibility in tuning the final properties of the material and in the manufacturing of the final product. In addition to “dial-a-size” capabilities, it also offers “dial-a-shape” and “dial-a-structure” capability through the self-assembled templates. It does not require any seeding to initiate the growth (seeds are impurities in the final product) and enables the growth of a great variety of materials. Finally, the process can be scaled up for industrial production.

The present invention relates to a process for synthesizing nanostructures. The process involves providing a first reactant, forming a liquid crystalline template containing the first reactant and contacting a gas phase made of a second reactant diluted in a carrier gas with the liquid crystalline template. The second reactant is then allowed to react with the first reactant under conditions effective to form nanostructures.

According to the present invention, the terms nanostructure and nanoparticle are used interchangeably and refer to crystalline entities or particles at the nanometer scale, i.e., entities having at least one dimension between about 1 and about 100 nanometers.

The present invention employs lyotropic liquid-crystal templates to control the size and shape of crystalline ZnSe nanostructures grown in the nanodomains formed by the dispersed phase. The templates are formed by self-assembly of a PEO-PPO-PEO amphiphilic block copolymer in a polar continuous phase (e.g. formamide) and in the presence of a non-polar dispersed phase (e.g. heptane). A Zn precursor, e.g. diethylzinc, is dissolved in the heptane before forming the template. By varying the composition of the ternary self-assembled system it is possible to selectively produce cubic liquid crystals with spherical nanodomains, hexagonal liquid crystals with cylindrical nanodomains, or lamellar liquid crystals with planar nanodomains. The size and shape of the heptane nanodomains and the concentration of diethylzinc in them can be used for controlling the size and shape of the nanocrystals. The nucleation of the nanocrystals is facilitated by a spontaneous and irreversible reaction between the diethylzinc and hydrogen selenide gas that is brought in contact with the template inside a sealed chamber and diffuses through the liquid crystal to react with diethylzinc. By selecting the appropriate template it is possible to manipulate the shape and size of the resulting nanostructures, and produce ZnSe quantum dots, nanowires, and self-standing nanodiscs.

Suitable first reactants and second reactants for use in the process of the present invention include any elements or compounds that are capable of reacting with one another to form a nanoparticle.

Suitable first reactants include metal-containing compounds. Exemplary metals include, without limitation, Zn, Cd, Hg, and Pb. Another example of a suitable first reactant includes an organometallic compound. Exemplary organometallic compounds include, without limitation, dimethyl-Zn, dimethyl-Cd, dimethyl-Hg, diethyl-Zn, diethyl-Cd, diethyl-Hg, tetramethyl-Pb, and tetraethyl-Pb. Preferably, the organometallic compound is diethyl-Zn, dimethyl-Zn, diethyl-Cd, or dimethyl-Cd.

According to the present invention, the liquid crystalline template is formed by providing a block copolymer, providing a polar continuous phase material, providing a dispersed nonpolar phase material, and then allowing the block copolymer, polar continuous phase material, and dispersed nonpolar phase material to come into contact with each other under conditions effective to form a liquid crystalline template.

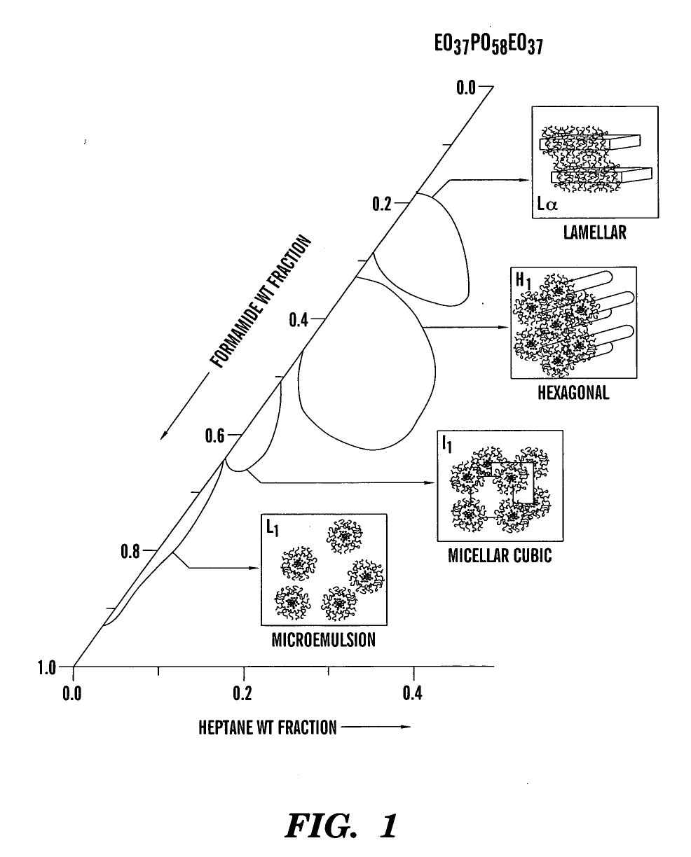

The liquid crystal templates were prepared at room temperature by mixing specific amounts of PEO-PPO-PEO block copolymer with formamide (CH₃NO) as the polar continuous phase and a 1 M solution of diethylzinc ((C₂H₅)₂Zn) in η-heptane (η-C₇H₁₆) as the dispersed nonpolar phase (Karanikolos et al., “Templated Synthesis of ZnSe Nanostructures Using Lyotropic Liquid Crystals”, Nanotechnology 16:2372-2380 (2005), which is hereby incorporated by reference in its entirety). The amount of each component depends on the liquid crystal phase of interest. The ternary phase diagram in FIG. 1 shows appropriate concentration ranges that can be used in order to form the various liquid crystalline phases, namely Micellar Cubic, Hexagonal, and Lamellar.

A number of poly(ethylene oxide)poly(propylene oxide)-poly(ethylene oxide) (PEO-PPO-PEO) triblock copolymers have been identified, which self-assemble under equilibrium conditions into a variety of lyotropic liquid crystalline microstructures having spherical, cylindrical, or planar domains or having an interconnected (bicontinuous) topology. Such an ability to form several ‘normal’ (oil-in-water) and ‘reverse’ (water-in-oil) structures at the same temperature has never before been observed in ternary systems of common surfactants with water and oil. Furthermore, the variety of structures formed by a PEO-PPO block copolymer in the presence of selective solvents is much greater than that of a block copolymer of a given block composition in the absence of solvents or even in the presence of homopolymers (Alexandridis et al., “A Record Nine Different Phases (Four Cubic, Two Hexagonal, and One Lamellar Lyotropic Liquid Crystalline and Two Micellar Solutions) in a Ternary Isothermal System of an Amphiphilic Block Copolymer and Selective Solvents (Water and Oil),” Langmuir 14(10):2627-2638 (1998), which is hereby incorporated by reference in its entirety). The excellent properties of PEO-PPO block copolymers as templates have been demonstrated for synthesis of mesoporous materials (Zhao et al., “Triblock Copolymer Syntheses of Mesoporous Silica with Periodic 50 to 300 Angstrom Pores,” Science 279:548-552 (1998); Soler-Illia et al., “Block Copolymer-Templated Mesoporous Oxides,” Curr. Opin. Colloid Interface Sci. 8(1):109-126 (2003), which are hereby incorporated by reference in their entirety) and metal nanostructures (Sakai et al., “Size- and Shape-Controlled Synthesis of Colloidal Gold Through Autoreduction of the Auric Cation by Poly (Ethylene Oxide)-Poly(Propylene Oxide) Block Copolymers in Aqueous Solutions at Ambient Conditions,” Nanotechnology 16:S344-S353 (2005), which is hereby incorporated by reference in its entirety), preparation of CdS nanorods (Yang et al., “Growth of CdS Nanorods in Nonionic Amphiphilic Triblock Copolymer Systems,” Chem. Mater. 14(3):1277-1284 (2002), which is hereby incorporated by reference in its entirety), and growth of ZnSe quantum dots (Karanikolos et al., “Synthesis and Size Control of Luminescent ZnSe Nanocrystals by a Microemulsion-Gas Contacting Technique,” Langmuir 20(3):550-553 (2004), which is hereby incorporated by reference in its entirety).

Examples of block copolymers include, without limitation, copolymers made by joining poly(ethylene oxide) or poly(acrylic acid) blocks with polystyrene or polybutylene or polydimethylsiloxane. An exemplary block copolymer includes a poly(ethylene oxide)-poly(propylene oxide)-poly(ethylene oxide) block copolymer. Exemplary surfactants for use in the present invention are natural (e.g., lipids), synthetic (e.g., alkyl benzyl sulfonates), ionic (e.g., sodium dodecyl sulfate), cationic (e.g., alkyl-trimethylammonium chloride), nonionic (e.g., alkyl ethoxylates), or zwitterionic (e.g. betaine). The surfactants can include single species (e.g., one type of molecule present) or mixtures of species (e.g., mixture of anionic and cationic surfactants, mixture of an ionic surfactant and an aliphatic alcohol). The surfactants can also be monodisperse or polydisperse. Examples of suitable water-dispersible polymers include dextran, guar gum, and gelatine. Examples of suitable solid particles for use in the present invention include silica, aluminum oxide, and titanium oxide. Suitable solvent-swollen particles include latexes.

Suitable polar continuous phase materials include, but are not limited to, any non-reactive polar solvent that does not react with either of the first reactant, the second reactant, the liquid crystal, or a product of the processes of the present invention. A preferred polar continuous phase material is formamide.

Suitable non-polar phase materials include, but are not limited to, aromatic hydrocarbons such as p-xylene and toluene. Preferred dispersed nonpolar phase materials include organic solvents, more specifically alkanes, and preferably η-heptane.

Suitable second reactants can be in the form of a gas or vapor. A particular suitable second reactant includes, for example, a Group VI element-containing compound. Exemplary Group VI elements include, without limitation, Se, S, Te, and O. In one embodiment, the second reactant is a Group VI element-containing compound in the form of a hydride (e.g., a hydride of Se, S, or Te). More particularly, the second reactant is H₂Se gas. In another embodiment, the second reactant is an oxygen-containing compound. Exemplary oxygen-containing compounds include, without limitation, molecular oxygen (O₂) gas, ozone (O₃) gas, or water (H₂O) vapor. In yet another embodiment, the second reactant is a Te-containing compound. Exemplary Te-containing compounds include, without limitation, vapors of dimethyl-Te, diethyl-Te, or diisopropyl-Te.

Suitable carrier gases for use in the present invention include any gas that does not react with either of the first reactant, the second reactant, the liquid crystal, or a product of the processes of the present invention. Exemplary carrier gases include, without limitation, hydrogen, nitrogen, helium, and argon.

According to the present invention, the contacting step encompasses bubbling the gas phase over the liquid crystalline template under conditions effective to allow the second reactant to diffuse into the template and to react with the first reactant, thus forming the nanostructures. Preferably, contacting is performed at a temperature at which the liquid crystalline template remains stable at atmospheric pressure or at a pressure higher than atmospheric pressure.

The ternary isothermal phase diagram of the EO₃₇PO₅₈EO₃₇-formamide-heptane system at room temperature was studied first in order to identify the relative amounts of the three components for forming the liquid crystal templates of interest. FIG. 1 shows the phase boundaries for the ‘normal’ (heptane-in-formamide) microemulsion (L₁) region, as well as the ‘normal’ micellar cubic (I₁), ‘normal’ hexagonal (H₁), and lamellar (Lα) lyotropic liquid crystalline regions. The microemulsion phase (L₁) included heptane nanodroplets dispersed in formamide, the micellar cubic liquid crystalline phase (I₁) included spherical nanodroplets arranged in a cubic lattice, the hexagonal liquid crystalline phase (H₁) included cylindrical nanodomains in a hexagonal arrangement, and the lamellar liquid crystalline phase (Lα) included alternating polar and non-polar planar nanodomains. The PEO-PPO-PEO block copolymer molecules were found to be localized at the interfaces of the nanodomains with their polar blocks (PEO) in formamide and their less-polar blocks (PPO) in η-heptane.

Samples were prepared inside flame-sealed glass tubes to avoid solvent evaporation, and were homogenized by repeated centrifugation over the course of several days. At equilibrium, the single-phase samples were clear and macroscopically homogeneous, whereas the two-phase samples were either homogeneous but opaque, or macroscopically heterogeneous/phase separated. Under polarized light, the microemulsion solution and cubic lyotropic liquid crystal samples were isotropic, while hexagonal and lamellar lyotropic liquid crystal samples were anisotropic/birefringent (Alexandridis et al., “A Record Nine Different Phases (Four Cubic, Two Hexagonal, and One Lamellar Lyotropic Liquid Crystalline and Two Micellar Solutions) in a Ternary Isothermal System of an Amphiphilic Block Copolymer and Selective Solvents (Water and Oil),” Langmuir 14(10):2627-2638 (1998); Alexandridis, P., “Structural Polymorphism of Poly(Ethylene Oxide)-Poly(Propylene Oxide) Block Copolymers in Nonaqueous Polar Solvents,” Macromolecules 31(20):6935-6942 (1998), each of which are hereby incorporated by reference in their entirety). Easy distinction between microemulsion solution and cubic liquid crystal samples was likely due to the fact that the former can easily flow, whereas the latter are gel-like.

The microemulsion or normal micellar solution region (L₁) was found to be stable in the formamide-rich corner of the ternary phase diagram of FIG. 1. In this region, PEO-PPO-PEO unimers self-assemble into spherical micelles, which have the ability to solubilize hydrophobic compounds, such as heptane, in their PPO core, as previously seen (Alexandridis et al., “Micellization of Polyoxyalkylene Block Copolymers in Formamide,” Macromolecules 33(9):3382-3391 (2000)), which is hereby incorporated by reference in its entirety). The microemulsion region was found to accommodate up to ˜1.7 wt % heptane. In previous work (Karanikolos et al., “Synthesis and Size Control of Luminescent ZnSe Nanocrystals by a Microemulsion-Gas Contacting Technique,” Langmuir 20(3):550-553 (2004), which is hereby incorporated by reference in its entirety), templates from the L₁ region of the above ternary system were employed to grow ZnSe quantum dots by a microemulsion-gas contacting technique that utilized the nanodroplets of the heptane dispersed phase as identical nanoreactors.

The normal micellar cubic phase (I₁) was found to be stable along the binary PEO-PPO-PEO/formamide axis in the 37-49 wt % copolymer concentration range (Alexandridis, P., “Structural Polymorphism of Poly(Ethylene Oxide)-Poly(Propylene Oxide) Block Copolymers in Nonaqueous Polar Solvents,” Macromolecules 31(20):6935-6942 (1998), which is hereby incorporated by reference in its entirety). The samples in this region are stiff and optically isotropic (non-birefringent). Both properties are characteristics of a cubic lyotropic liquid crystalline gel. The location of this region in the ternary phase diagram according to FIG. 1 (between the micellar solution and the hexagonal phase), as well as small-angle x-ray scattering (SAXS) data reported for the binary PEO-PPO-PEO/formamide system, confirm that its microstructure is composed of normal micelles that have been crystallized into a cubic lattice (Alexandridis et al., “A Record Nine Different Phases (Four Cubic, Two Hexagonal, and One Lamellar Lyotropic Liquid Crystalline and Two Micellar Solutions) in a Ternary Isothermal System of an Amphiphilic Block Copolymer and Selective Solvents (Water and Oil),” Langmuir 14(10):2627-2638 (1998); Alexandridis, P., “Structural Polymorphism of Poly(Ethylene Oxide)-Poly(Propylene Oxide) Block Copolymers in Nonaqueous Polar Solvents,” Macromolecules 31(20):6935-6942 (1998), each of which are hereby incorporated by reference in their entirety).

The normal hexagonal region (H₁) was shown to be stable in the 56-67 wt % copolymer range along the binary PEO-PPO-PEO/formamide axis. Samples in this region are composed of cylindrical self-assemblies crystallized in a hexagonal lattice, as has been shown by SAXS data for the binary PEO-PPO-PEO/formamide system (Alexandridis, P., “Structural Polymorphism of Poly(Ethylene Oxide)-Poly(Propylene Oxide) Block Copolymers in Nonaqueous Polar Solvents,” Macromolecules 31(20):6935-6942 (1998), which is hereby incorporated by reference in its entirety).

The lamellar phase region (Lα) was shown to be stable in the 72-81 wt % copolymer range along the binary PEO-PPO-PEO/formamide axis and was composed of alternating polar and non-polar layers (Alexandridis, P., “Structural Polymorphism of Poly(Ethylene Oxide)-Poly(Propylene Oxide) Block Copolymers in Nonaqueous Polar Solvents,” Macromolecules 31(20):6935-6942 (1998), which is hereby incorporated by reference in its entirety).

Thus, using the ternary phase diagram of FIG. 1, it is possible to identify the relative amounts of the three components for forming the liquid crystal templates of interest.

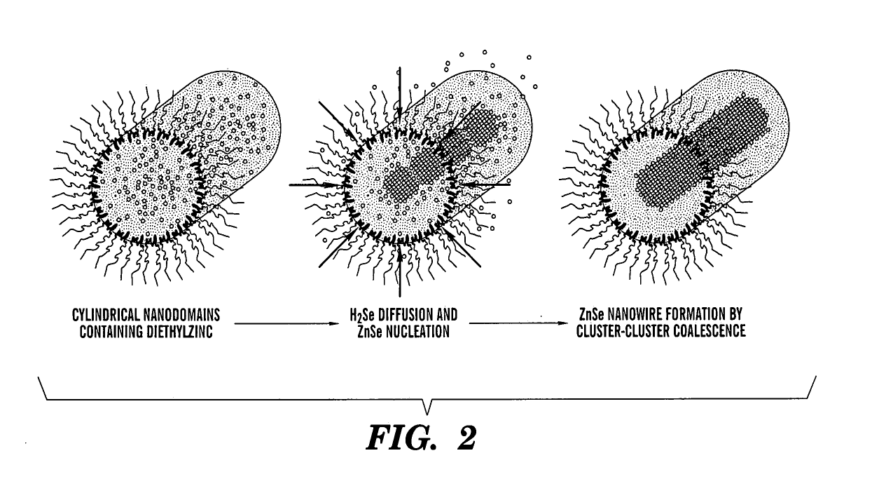

The synthesis of ZnSe quantum dots, nanowires, and nanodiscs was performed using liquid crystal templates, synthesized according to the present invention, containing diethylzinc in the heptane dispersed phase. The mechanism of nanowire growth in liquid crystals with cylindrical nanodomains (H₁ phase) is shown schematically in FIG. 2. The synthesis of quantum dots in liquid crystals with spherical nanodomains (I₁ phase) and nanodiscs in liquid crystals with planar nanodomains (Lα phase) follows a similar mechanism as that shown in FIG. 2.

In previous work it was demonstrated that the reaction between hydrogen selenide gas and diethylzinc dissolved in the heptane dispersed phase of a PEO-PPO-PEO/heptane/formamide microemulsion results in the formation of cubic (zinc blende) ZnSe quantum dots at room temperature (Karanikolos et al., “Synthesis and Size Control of Luminescent ZnSe Nanocrystals by a Microemulsion-Gas Contacting Technique,” Langmuir 20(3):550-553 (2004), which is hereby incorporated by reference in its entirety).

Generally, when a H₂Se/H₂ mixture comes into contact with a liquid crystal, H₂Se diffuses through the formamide matrix and the PEO-PPO-PEO layer surrounding the nanodomains formed by the heptane. As soon as it reaches the heptane it reacts with diethylzinc leading to nucleation of ZnSe clusters. These clusters subsequently grow by cluster-cluster coalescence to eventually form a single nanostructure in each nanodomain.

ZnSe quantum dots were synthesized inside the spherical nanodomains of the cubic micellar liquid crystalline phase (I₁) of the PEO-PPO-PEO/heptane/formamide system with a mechanism similar to that shown in FIG. 2. After the cubic liquid crystals containing diethylzinc were prepared, they were brought into contact with a 5% mixture of H₂Se in H₂ inside a sealed chamber for 12 hrs. The H₂Se diffused inside the liquid crystal, penetrated the PEO-PPO-PEO layer, and reacted with diethylzinc inside the spherical nanodomains to yield ZnSe nanocrystals.

The mechanism for synthesis of one-dimensional nanostructures in the cylindrical nanodomains of hexagonal liquid crystals is shown schematically in FIG. 2. Reaction between the two precursors, i.e., diethylzinc and H₂Se, and nucleation of ZnSe clusters occurs throughout each nanocylinder. The clusters subsequently grow by cluster-cluster coalescence to form a single ZnSe nanowire in each cylindrical domain.

ZnSe nanodiscs were synthesized inside the planar nanodomains of the PEO-PPO-PEO/heptane/formamide lamellar phase with a technique similar to the one used for nanowire synthesis, shown schematically in FIG. 2. The liquid crystal containing diethylzinc dissolved in the heptane nanodomains was brought into contact with H₂Se gas. The irreversible reaction between the precursors led to nucleation of ZnSe and formation of ZnSe nanodiscs in the planar nanodomains by a coalescence mechanism.

According to the present invention, the nanostructures which are produced can be nanoparticles having a diameter of between about 1 and about 100 nanometers. In addition, the nanoparticles produced by the processes of the present invention can be of various forms, including, for example, nanoparticles of crystalline form, polycrystalline form, or amorphous form. In one embodiment, the nanoparticles are nanocrystals. In particular, the nanoparticles can be single crystals that exhibit long-range order of the atoms contained in each nanoparticle that extend continuously over the entire mass of the nanoparticle. The nanoparticles can also be polycrystalline particles, including particles composed of sintered single-crystalline grains (Sarigiannis et al., “Characterization of Vapor-Phase-Grown ZnSe Nanoparticles,” Appl. Phys. Lett. 80(21):4024-4026 (2002), which is hereby incorporated by reference in its entirety). Further, the nanoparticles can be amorphous particles exhibiting no long-range order of the atoms that form them. The shape of the individual particles can be arbitrary, for example, spherical, or rod-like. However, the individual particles can also have other shapes such as dumbbells, discs, or aggregates of smaller particles that form dendrite-like structures.

The nanoparticles produced by the process of the present invention can have various attributes. For example, the nanoparticles can exhibit size-dependent luminescence and/or fluorescence. The nanoparticles can also be of various compositions. For example, the nanocrystals can be luminescent Group II-Group VI nanocrystals of the form MX, where M is Zn, Cd, or Hg, and where X is Se, S, Te, or O. More particularly, the nanocrystals can include, for example, ZnSe, ZnS, ZnTe, CdSe, CdS, CdTe, PbSe, and PbS nanocrystals. In a specific embodiment, the nanocrystals are ZnSe or CdSe nanocrystals having a diameter of between about 1 and about 100 nanometers.

ZnSe is a direct band gap semiconductor with a band gap of 2.7 eV at room temperature, which makes it suitable for the fabrication of short wavelength devices such as blue—green lasers, photodetectors, and light-emitting diodes.

The processes of synthesizing nanostructures according to the present invention further include incorporating a functional material onto the surface of the nanostructure. This functional material can be dissolved in a solvent prior to the contacting step of the synthesizing process, can be added to the outer surface of the nanoparticle, and can include either a thiol-based compound or an amine-based compound. Suitable solvents include aliphatic hydrocarbons including heptane and octane. Additional suitable solvents include aromatic hydrocarbons including p-xylene and toluene.

In addition to producing monodisperse assemblies of nanocrystals, the process of the present invention can be used to simplify the functionalization of nanocrystals. Hybrid nanocrystal-polymer composites can be synthesized by adding polymerizable surface ligands in the dispersed phase. For example, 4-thiomethyl styrene can serve both as a capping agent for the nanocrystals and as a co-monomer in the polymerization of styrene, after the particles have been dispersed in it. This can allow for the synthesis of photonic materials having nanocrystals as the building blocks (active centers) in a polymer matrix composed of macromolecular tethers between the nanocrystals.

Using the process of the present invention, a class of functional materials, inorganic-organic composite nanocrystals including a semiconductor core and a polymer corona, can be developed by a number of synthesis routes. These synthesis routes can include, for example, the following: (a) the nanocrystal surface can be capped with thiols possessing a reactive end-group, which can be used to attach or grow a polymer chain; (b) the nanocrystal surface can be coated with silicon oxide, and well-established silane chemistry can be used to chemically attach polymers (Gerion et al., “Synthesis and Properties of Biocompatible Water-Soluble Silica-Coated CdSe/ZnS Semiconductor Quantum Dots,” J. Phys. Chem. B. 105:8861-8871 (2001), which is hereby incorporated by reference in its entirety); and (c) the nanocrystals can be placed in the dispersed phase of a suspension polymerization process (Odian, G., “Principles of Polymerization,” Wiley, 3^{rd} ed. (1991), which is hereby incorporated by reference in its entirety) and the monomer allowed to polymerize around them, producing latex beads containing several nanocrystals.

Alternatively, an initiator can be attached to the nanocrystals, followed by emulsion polymerization, resulting in a single polymer chain coating a single nanocrystal. In addition to the above “chemical” approaches, “physical” binding of polymers to nanocrystals can occur upon suspension in a solvent containing dissolved high-molecular weight polymer. Following polymer adsorption (Lin et al., “Adsorption of a Rake-Type Siloxane Surfactant Onto Carbon Black Nanoparticles Dispersed in Aqueous Media,” Langmuir 18:6147-6158 (2002); Lin et al., “Adsorption Properties of a Polymeric Siloxane Surfactant Onto Carbon Black Particles Dispersed in Mixtures of Water With Polar Solvents,” J. Colloid Interface Sci. 255:1-9 (2000); Lin et al., “Adsorptoin of Amphiphilic Copolymers on Hydrophobic Particles in Aqueous Media,” J. Disp. Sci. Tech. 23:539-553 (2002); Lin et al., “Temperature-Dependent Adsorption of Pluronic F127 Block Copolymers Onto Carbon Black Particles Dispersed in Aqueous Media,” J. Phys. Chem. B. 106:10834-10844 (2002), each of which are hereby incorporated by reference in their entirety) on the nanocrystals and the removal of the solvent by spray drying, porous polymer particles, each containing many ZnSe nanocrystals, can be obtained. Alternatively, the precipitation of the polymer on the particle surface, following a worsening of the solvent quality, can result in a suspension of polymer-coated ZnSe nanocrystals.

The process of synthesizing nanostructures according to the present invention further includes isolating the nanoparticles which can be substantially the same size and will be dependent on the initial concentration of the first reactant prior to the contacting step of the synthesizing process.

The present invention also relates to a liquid crystalline template produced by providing a block copolymer, providing a polar continuous phase material, providing a dispersed nonpolar phase material, and then allowing the block copolymer, polar continuous phase material, and dispersed nonpolar phase material to come into contact with each other under conditions effective to form a liquid crystalline template.

The block copolymer is made of, although not limited to, poly (ethylene oxide) and poly (propylene oxide), as described according to the present invention.

Suitable polar continuous phase materials include, but are not limited to, any polar solvent that does not react with either of the first reactant, the second reactant, the liquid crystal, or a product of the processes of the present invention. One preferred polar continuous phase material is formamide.

Suitable non-polar phase materials include, but are not limited to, aromatic hydrocarbons such as p-xylene and toluene. Preferred dispersed nonpolar phase materials include organic solvents, more specifically alkanes, and preferably η-heptane.

Structural, morphological, and chemical characterization of the nanocrystals, nanoparticles, and nanstructures of the present invention, can be performed by using transmission electron microscopy (TEM), atomic force microscopy (AFM), energy dispersive analysis of X-rays, and optical spectroscopy (Raman, transmission and photoluminescence). By measuring the effective band gap of these materials using transmission spectroscopy, the increase in gap with decreasing nanoparticle size and the variation of bandgap with composition in ternary materials can be precisely recorded. The characterization of DMS nanocrystals and the corresponding polymer-nanocrystal hybrids will focus on measurements of magneto-optical effects by applying a variable external magnetic field. An 8-Tesla superconducting magnet with a Janis optical cryostat can be used. Characterization of the chemical attachment on the surface can be done by spectroscopic means or by solvent treatment aimed to remove non-covalently attached material. ESCA/XPS can be used to quantify the surface atom composition prior to and following the polymer attachment/adsorption. SEM and TEM can be used to measure the corona thickness (because the polymer has a very different electron density than ZnSe) and the state of aggregation (number of ZnSe nanoparticles per composite particle). The amount of polymer present can be determined from a material balance (involving the weights of the reactants and product) and/or from a thermogravimetric analysis where the organic material is burned off while the inorganic material forms oxides.

The nanoparticles and various nanostructures of the present invention can be used in various applications in clinical diagnostics and proteomics. Such suitable applications are included below by way of example. In particular, the development of “sandwich-type” immunoassays using fluorescent nanocrystals (quantum dots) can be achieved. This immunoassay can be used to detect antigens (e.g., drugs, proteins, or biological infectious agents), using the specific binding between an antibody and the antigen under scrutiny. In multiplexing form, a sandwich-type immunoassay can be used to simultaneously detect several antigens using two populations of antibodies that can selectively bind each antigen. As an example, suitable components of the assay can include: (1) a surface (e.g., the inner surface of a cavity) functionalized with streptavidin; (2) a population of a biotinylated antibody for each antigen to be detected (e.g., an antibody linked to biotin, which is a protein that has high affinity for streptavidin); and (3) a second population of a labeled antibody for each antigen to be detected (e.g., an antibody that has been linked to semiconductor nanocrystals of specific size that can fluoresce at a specific wavelength). A different population of nanocrystals can be used to label the antibodies of different antigens. Further, the nanocrystal populations can be chosen to emit at distinct wavelengths that can be detected simultaneously and uniquely when all populations are present in the same solution.

As an example, the detection of the antigens can be achieved using the following steps: (1) exposure of the surface of the cavity to an aqueous solution containing the biotynilated antibody populations and incubation for a few minutes to allow binding of the antibodies to the surface; (2) a wash step with water to remove the unbound biotynilated antibodies; (3) exposure of the surface to the sample that possibly contains the antigens to be detected and incubation for a few minutes to allow specific binding of the antigens to the biotinylated antibodies that are bound to the surface; (4) a wash step with water to remove all unbound matter; (5) exposure to an aqueous solution containing the labeled antibody populations and incubation for a few minutes to allow specific binding of the labeled antibodies with the antigens; (6) a wash step with water to remove all unbound material from the cavity; (7) the cavity is exposed to UV light with wavelength shorter than the smallest wavelength at which emission is expected from the nanocrystals; (8) detection of emitted light from the surface at a specific wavelength, corresponding to the labeled antibodies of a certain antigen, provides a positive detection of the antibody in question; (9) multiplexing is achieved by the ability to simultaneously detect several antigens; and (10) quantitative analysis can be achieved by calibrating the intensity of the emitted light with known concentrations of the corresponding antigen. A variation of the above procedure for speedup of the detection time utilizes a mixture of all antibody populations and the sample and a single incubation step followed by a wash step. This procedure can be useful when multiplexing is not essential but a quick response time is needed, such as for detection of biological warfare agents in the field.

The nanoparticles and nanostructures of the present invention can also be used in coatings, cosmetics, and surface treatments. For example, a nanostructure-loaded emulsion can be used in formulations of surface coatings (e.g., paints) that respond to UV light from natural (e.g., from the sun) or manmade sources (e.g., UV lamps). The formulations may include additional components, such as inorganic particles (for opacity) and polymeric particles (for film formation). These coatings will change color when the UV source is present and return to their original color (or transparency) when the UV source is eliminated. Potential applications can include, for example: (1) applications related to camouflage of equipment that include coatings and patterns attaining specific colors during the day by utilizing the luminescence of the nanocrystals and a different color at night when the excitation from the sun's UV radiation is not present; (2) architectural, automotive, and general-purpose coatings that can change color when exposed to sunlight due to emission from the nanocrystals and attain a different color at night; (3) cosmetics that respond to sunlight with a temporary change of color enabled by the luminescence of the nanocrystals (the original color (or transparency) is recovered when the UV source is eliminated); and (4) apparel that contain such nanocrystal formulations providing the ability to change color when exposed to a UV source and to recover the original color upon elimination of the UV radiation (for civilian or military applications).

One-dimensional nanostructures, such as nanowires according to the present invention, that confine electron-hole pairs in one dimension can be used for fundamental studies in mesoscopic physics and as interconnects and functional units in nanoelectronics. Such nanocrystals represent the smallest dimension for efficient transport of electrons and excitons and thus are ideal building blocks for hierarchical assembly of functional electronic and photonic structures.

In one embodiment, the present invention employs precise manipulation of shape and structure of nanoparticles by utilizing stable liquid crystalline templates which are self-assembled using precisely controlled proportions of a polar solvent (e.g. formamide), a non-polar solvent (e.g. heptane) and an amphiphilic block copolymer (e.g. polyethylene oxide-polypropylene oxide-polyethylene oxide).

### EXAMPLES

The following examples are provided to illustrate embodiments of the present invention but are by no means intended to limit its scope.

### Example 1

### Formation of Liquid Crystalline Templates Using Formamide and Heptane

A mixture composed of 47 wt % PEO-PPO-PEO, 52 wt % formamide, and 1 wt % η-heptane was used to produce a cubic liquid crystalline phase. Using the above mixture composition, a total mass of 1 gram was used, which corresponded to 0.47 g PEO-PPO-PEO, 0.52 g formamide, and 0.01 g η-heptane. The diethylzinc concentration in the heptane can be manipulated in order to control the final nanocrystal size. In this particular example a 1 M diethylzinc concentration in η-heptane was used, however the concentration of diethylzinc in η-heptane can range from 0.0001 M to 10 M. It is possible to tune the diethylzinc concentration in heptane to any value in order to obtain a desired final nanocrystal size, i.e. more diethylzinc in η-heptane equals a larger nanocrystal. The sample was prepared inside glass vials equipped with a septum cap. A glove bag (AtmosBag, purchased from Aldrich) filled with N₂ was used to mix the components since diethylzinc is air-sensitive. The inlet of the bag was connected to a N₂ cylinder and the outlet to a vacuum pump, through two metering valves that were used to control the gas flow and the vacuum, respectively. The items initially put inside the glove bag included septum vials containing 0.47 g PEO-PPO-PEO (cap separate), pipette and pipette tips, a 10 cc plastic syringe, a 4 inch long 22-gauge needle, an empty 1-dram vial, a vial containing the formamide, the 1 M diethylzinc/heptane solution bottle, paraffin tapes, and wipers. After the bag was sealed, a series of 8 evacuation/purging cycles was initiated in order to remove the air and replace it with N₂. Working with the bag glove, 0.52 grams formamide were transferred into the septum vial using the pipette. Subsequently, about 1 ml of the diethylzinc/heptane solution was transferred from the bottle into the empty vial with the syringe/needle assembly. Then 0.01 grams of the solution was taken from the vial and transferred into the septum vial using the pipette. The vial was capped firmly and paraffin tape was applied around the cap for better sealing. Finally, the bag was opened and the sample removed for centrifugation. The sample was centrifuged repeatedly at 3,000 rpm in alternating directions, for 2 minutes in each direction, to facilitate homogenization. After the mixture was homogenized, it was left to equilibrate over the course of several days, preferably approximately 1 week, until an optically isotropic and transparent gel was obtained, which indicated liquid crystal formation. The sample was subsequently placed in a polarized light device in order to visually inspect and identify the liquid crystalline phase. For example, under polarized light, cubic liquid crystals are isotropic/non-birefringent, whereas hexagonal liquid crystals are anistropic/birefringent.

Using the procedures described above, different liquid crystal templates were formed by simply varying the relative amounts of block copolymer, e.g., PEO-PPO-PEO, polar continuous phase material, e.g., formamide, and nonpolar phase material, e.g., η-heptane according to the concentration ranges presented in FIG. 1.

All chemicals were used ‘as received’ without any additional purification. Care was taken to avoid exposure of the hygroscopic formamide and PEO-PPO-PEO block copolymer to atmospheric moisture. Standard airless techniques were used to avoid exposure of diethylzinc to oxygen and moisture. Diethylzinc (1 M solution in η-heptane) and formamide (99.5+%) were purchased from Aldrich, η-heptane (99.9%) was purchased from VWR International, and electronic-grade hydrogen selenide gas (5% mixture with hydrogen) was purchased from Solkatronic Chemicals. The Pluronic P105 PEO-PPO-PEO block copolymer (with molecular formula: EO₃₇PO₅₈EO₃₇ according to its nominal MW of 6500 and 50% PEO content) was obtained from BASF Corporation.

Photoluminescence (PL) emission spectra were obtained by dissolving a sample containing the ZnSe nanocrystals in 200 proof ethanol, loading the solution into quartz cuvettes, and analysing it using a 0.5 m single-stage spectrometer (CVI Laser Corp.) equipped with a thermoelectrically cooled multichannel CCD detector (camera AD-205 working in the wavelength range of 200-1100 nm). A 325 nm line of a 35 mW He—Cd UV laser (Melles Griot) was used to excite the nanocrystals. The samples used for transmission electron microscopy (TEM) were prepared by placing a drop of the ethanol solution on a 400-mesh carbon-coated copper grid (purchased from Ernest F. Fullam, Inc.). The instrument used was a JEOL JEM 2010 high-resolution transmission electron microscope, operated at 200 kV, with a point-to-point resolution of 0.193 nm. Samples for x-ray diffraction analysis were prepared by depositing a few drops of the ethanol nanocrystal dispersion on a clean silicon wafer and evaporating the solvents in a fume hood. The instrument used was a Siemens D500 XR x-ray diffractometer.

### Example 2

### Templated Synthesis of ZnSe Nanostructures

A septum vial containing a liquid crystal template according to the present invention, whose thickness was approximately 1 mm, was placed inside a reactor. The reactor was a tubular stainless steel chamber with a diameter of 1 inch that was used to accommodate the vial containing the template. The air was removed from the system by a pulling vacuum for 15 min and a subsequent 20 min flow of N₂ into the system. The reactor was equipped with an inner tube with a diameter of ¼ inch that was used for the transfer of gas. Under 1 atm of N₂, the reactor inner tube was inserted into the vial through the septum, which allowed contact between the liquid crystal and the surrounding gas. The N₂ was subsequently removed by evacuation, and the reactor immediately backfilled with a 5% H₂Se in H₂ gas mixture, at room temperature, until a pressure of 1 atm was obtained. A 6-hour contact between H₂Se and the Zn-doped liquid crystal was found to be sufficient to convert all diethylzinc into ZnSe.

After the reaction, five cycles of evacuation/backfilling with N₂ were performed in order to remove all traces of H₂Se, and the reactor subsequently passed through a tubular cracking furnace at a temperature higher than 200° C. before being released into a fume hood. The experiment was performed under a vented enclosure and a hydride detector was used to ensure personnel safety. The vial was taken out of the reactor, then capped and transferred to a fume hood where approximately 0.01 g of the processed liquid crystal, having a yellow coloration, was dissolved in about 2 ml of anhydrous ethanol (200 proof) in order to perform nanocrystal characterization.

The overall reaction that forms ZnSe is: H₂Se+Zn (C₂H₅)₂→ZnSe₍ₛ₎+₂C₂H_{6(g)}. This reaction occurs spontaneously at room temperature and is exothermic with a heat of reaction equal to −380 kJ mol⁻¹ (Karanikolos et al., “Synthesis and Size Control of Luminescent II-VI Semiconductor Nanocrystals by a Novel Microemulsion-Gas Contacting Technique,” Mater. Res. Soc. Symp. Proc. 789:389 (2004), which is hereby incorporated by reference in its entirety). A similar reaction has been used for growing single-crystalline thin films of ZnSe by metallorganic vapour phase epitaxy (MOVPE) (Peck et al., “Metalorganic Vapor Phase Epitaxy of Zn₁₋ₓFeₓSe Films,” J. Cryst. Growth 170(1-4):523-527 (1997), which is hereby incorporated by reference in its entirety), and ZnSe nanoparticles by vapour-phase processing (Sarigiannis et al., “Characterization of Vapor-Phase-Grown ZnSe Nanoparticles,” Appl. Phys. Lett. 80(21):4024-4026 (2002), which is hereby incorporated by reference in its entirety).

The most probable explanation for the formation of single-crystalline nanostructures by the present technique (and other room-temperature techniques (Leppert et al., “Structural and Optical Characteristics of ZnSe Nanocrystals Synthesized in the Presence of a Polymer Capping Agent,” Mater. Sci. Eng. B 52(1):89-92 (1998); Kumbhojkar et al., “Quantum Confinement Effects in Chemically Grown, Stable ZnSe Nanoclusters,” Nanostruct. Mater. 10(2):117-129 (1998); Quinlan et al., “Reverse Micelle Synthesis and Characterization of ZnSe Nanoparticles,” Langmuir 16(8):4049-4051 (2000); Karanikolos et al., “Synthesis and Size Control of Luminescent ZnSe Nanocrystals by a Microemulsion-Gas Contacting Technique,” Langmuir 20(3):550-553 (2004), which are hereby incorporated by reference in their entirety) is an annealing mechanism due to the energy released during coalescence of small nanocrystals and clusters to form the final particle (Lehtinen et al., “Effect of Coalescence Energy Release on the Temporal Shape Evolution of Nanoparticles,” Phys. Rev. B 63:205402-205409 (2001), which is hereby incorporated by reference in its entirety). The energy released is due to the minimization of the unsaturated surface bonds. The annealing is aided by a depression of the melting point with particle size, which is expected to be similar to the melting point depression reported for CdS nanocrystals (Goldstein et al., “Meeting in Semiconductor Nanocrystals,” Science 256:1425-1427 (1992), which is hereby incorporated by reference in its entirety). Due to the melting point depression, the annealing can proceed at much lower temperatures than the ones required for annealing of bulk crystals. Modeling of thermal effects during cluster and nanocrystal coalescence in the templates presented here indicates that the energy release during coalescence is sufficient to locally raise the temperature of the resulting nanocrystals to enable annealing (and even melting), before energy dissipation by conduction to the surrounding medium can cool the nanocrystals back to room temperature (Kostova et al., “Multi-Scale Models of the Synthesis of Compound Semiconductor Nanocrystals (Quantum Dots) Using Microemulsions as Templates,” AIChE Annual Mtg (Austin, Tex., Nov. 2004) paper 590 g (manuscript in preparation) (2005), which is hereby incorporated by reference in its entirety). The net energy released during this process is very small and the macroscopically observed temperature of the system remains at room temperature.

### Example 3

### Synthesis of ZnSe Quantum Dots

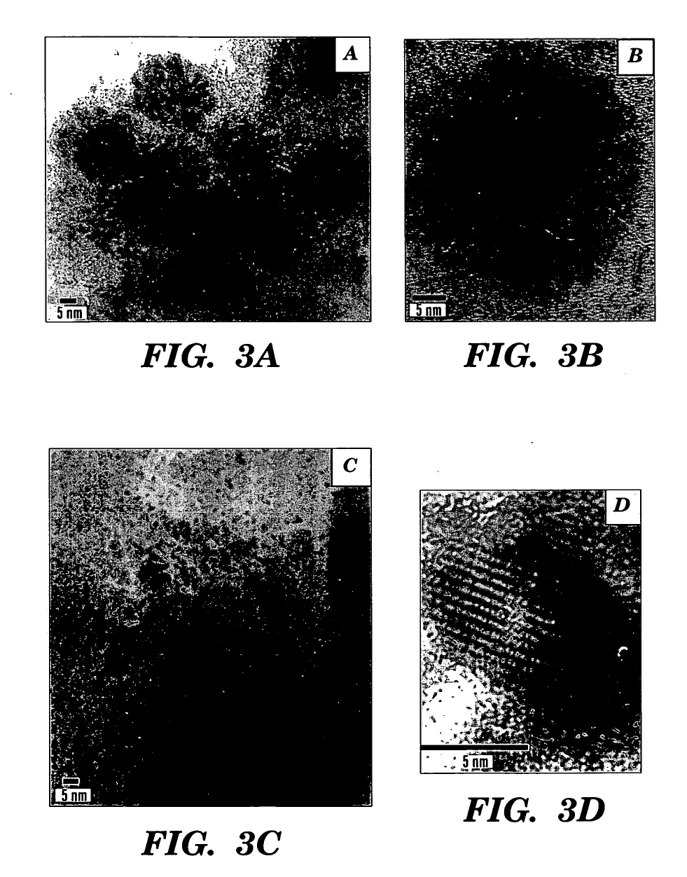

TEM images of the synthesized ZnSe quantum dots using different liquid crystal compositions are shown in FIGS. 3A-D. FIGS. 3A and 3B correspond to a template composition of 40 wt % EO₃₇PO₅₈EO₃₇, 58 wt % formamide, and 2 wt % of 1 M diethylzinc solution in heptane, while FIGS. 3C and 3D correspond to a template composition of 47 wt % EO₃₇PO₅₈EO₃₇, 52 wt % formamide, and 1 wt % of 1 M diethylzinc solution in heptane, which fall inside the cubic micellar region of the phase diagram shown in FIG. 1. Using these liquid templates, the production of the nanostructures was completed as described above. The synthesized nanocrystals have an average diameter of ˜3 nm. In order for the TEM analysis to be carried out, the liquid crystal template containing the nanocrystals was dispersed in ethanol, a few drops of the dispersion were placed on a TEM grid, and the solvents were evaporated in a fume hood. After solvent evaporation, the first sample, prepared from 40 wt % EO₃₇PO₅₈EO₃₇, 58 wt % formamide, and 2 wt % of 1 M diethylzinc solution in heptane, yielded spherical domains with size of 30-40 nm which included nanocrystals separated from each other, most probably due to a coating of block copolymer on their surface (FIGS. 3A and 3B). The second sample, prepared from 47 wt % EO₃₇PO₅₈EO₃₇, 52 wt % formamide, and 1 wt % of 1 M diethylzinc solution in heptane, resulted in a more uniform distribution of nanocrystals in a block copolymer matrix (FIG. 3C), most probably due to higher block copolymer content of the second template. FIG. 3D shows a high-resolution TEM image of a quantum dot synthesized from the second template that demonstrates the crystalline structure of the material. The scale bars correspond to 5 nm.

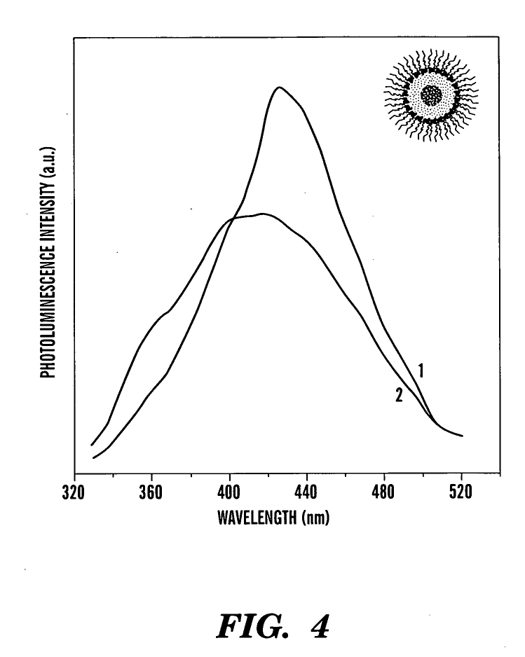

The room-temperature photoluminescence spectra obtained from two different quantum dot samples are shown in FIG. 4. Curve 1 corresponded to a template made of 40 wt % EO₃₇PO₅₈EO₃₇, 58 wt % formamide, and 2 wt % of 1 M diethylzinc solution in heptane, whereas curve 2 corresponded to a template made of 47 wt % EO₃₇PO₅₈EO₃₇, 52 wt % formamide, and 1 wt % of 1 M diethylzinc solution in heptane. The emission wavelengths of both spectra were below the expected emission wavelength from bulk ZnSe (460 nm), thus indicating quantum confinement. The emission peak of the second sample was blue-shifted compared to that of the first one, indicating that the average particle size for the second sample was smaller. This decrease in the nanocrystal diameter was due to the smaller diameter of the spherical nanodomains in the second template and not due to a change in concentration of the Zn precursor in heptane. The size of the nanocrystals can also be tuned by manipulating the concentration of diethylzinc in the heptane nanodomains. Suitable concentrations range from 0.0001 M to 10 M of diethylzinc. This same approach has been demonstrated in previous work employing microemulsion templates for ZnSe quantum dot synthesis (Karanikolos et al., “Synthesis and Size Control of Luminescent ZnSe Nanocrystals by a Microemulsion-Gas Contacting Technique,” Langmuir 20(3):550-553 (2004), which is hereby incorporated by reference in its entirety).

### Example 4

### Synthesis of ZnSe Nanowires

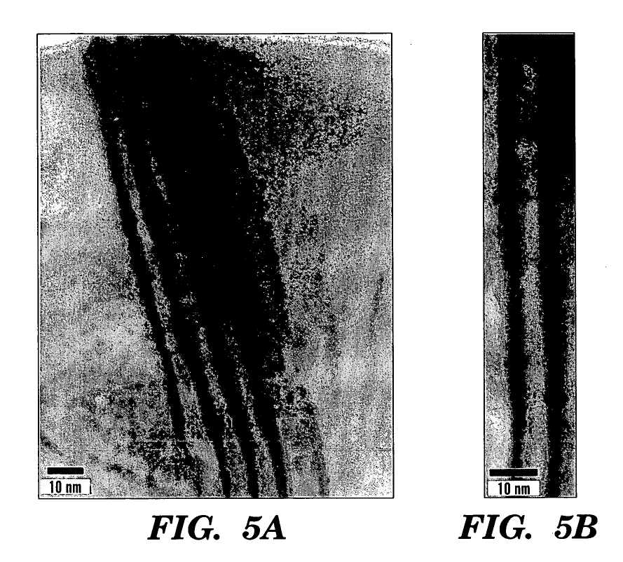

FIGS. 5A-B show TEM images of ZnSe nanowires with an average diameter of 3 nm synthesized using different liquid crystal compositions. The liquid crystal template was composed of 51.5 wt % EO₃₇PO₅₈EO₃₇, 39.6 wt % formamide, and 8.9 wt % of 1 M diethylzinc solution in heptane. Using these liquid templates, the production of the nanostructures was completed as described above. This composition falls into the hexagonal region of the phase diagram (FIG. 1). According to SAXS data for the binary PEO-PPO-PEO/formamide system, the radius of the cylindrical PPO domains is 3.4 nm and the nearest neighbour (cylinder) distance is 11.7 nm at 60/40 wt % polymer/formamide (Alexandridis, P., “Structural Polymorphism of Poly(Ethylene Oxide)-Poly(Propylene Oxide) Block Copolymers in Nonaqueous Polar Solvents,” Macromolecules 31(20):6935-6942 (1998), which is hereby incorporated by reference in its entirety). In the present invention, the radius of the cylindrical nanodomains was expected to be larger due to swelling caused by the presence of heptane inside them. In the TEM images, the nanowires appeared to be arranged parallel to each other. The separation distance between adjacent nanowires was approximately constant with an average value of about 6 nm. Since the expected length of the PEO tails was about half this distance (Alexandridis et al., “Self-Assembly of Amphiphilic Block Copolymers: The (EO)13(PO)30(EO) 13-Water-p-Xylene System,” Macromolecules 28(23):7700-7710 (1995), which is hereby incorporated by reference in its entirety), this indicated that after evaporation of the solvents the surface of the nanowires was coated by a single block copolymer layer with the PEO block pointing outwards, thus sterically hindering nanowire aggregation. The TEM results also showed the presence of ZnSe nanoparticles near the nanowires that can be attributed to the following two factors: (1) trapping of particles into the block copolymer layer that prevented their coalescence into nanowires, and/or (2) reaction of H₂Se with a small amount of diethylzinc that dissolved into formamide during the template formation. This partitioning can also be attributed to the finite solubility of heptane in formamide, which is (1.14±0.09)10⁻² M at 25° C. (Berling et al., “Solvation of Small Hydrophobic Molecules in Formamide—A Calorimetric Study,” J. Solution Chem. 23:911-923 (1994), which is hereby incorporated by reference in its entirety).

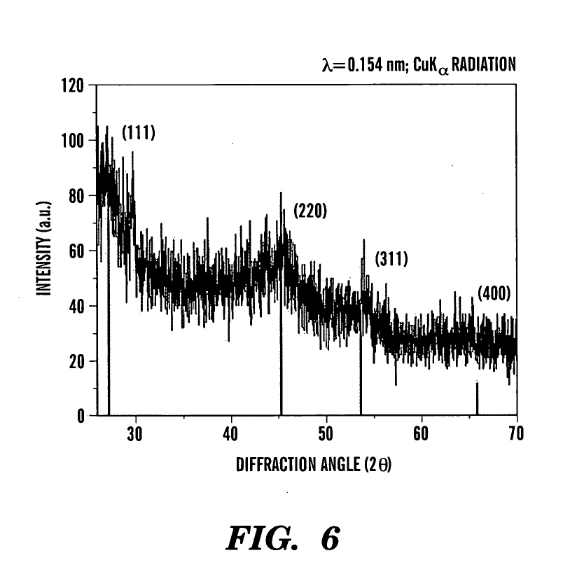

The x-ray diffraction pattern from the synthesized nanowires, as shown in FIG. 6, confirmed crystalline ZnSe. The nanowires, for which the x-ray diffraction pattern is shown in FIG. 6, were synthesized by using a template composition of 52.4 wt % EO₃₇PO₅₈EO₃₇, 38.1 wt % formamide, and 9.5 wt % of 1 M diethylzinc solution in heptane. The observed diffraction peaks matched the standard peaks at 27.2°, 45.2°, 53.6°, and 65.8° that correspond to the diffraction angles from the (111), (220), (311), and (400) planes of cubic (zinc-blende) ZnSe. The diffraction pattern appeared noisy because the mass ratio of ZnSe nanowires to block copolymer was very small (of the order of 3 wt %) in the samples obtained after solvent evaporation.

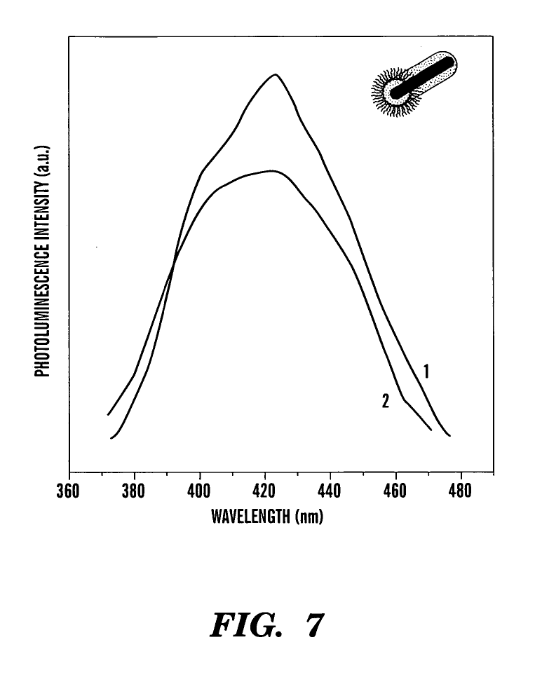

The ZnSe nanowires are luminescent at room temperature and exhibit quantum confinement, due to their small diameter. The bulk exciton Bohr diameter for ZnSe, below which quantum confinement is expected, is 9 nm and the bulk emission wavelength is 460 nm. FIG. 7 shows PL emission spectra of nanowires synthesized using two different template compositions. Curve (1) corresponds to 51.5 wt % EO₃₇PO₅₈EO₃₇, 39.6 wt % formamide, and 8.9 wt % of 1 M diethylzinc solution in heptane, and curve (2) corresponds to 52.4 wt % EO₃₇PO₅₈EO₃₇, 38.1 wt % formamide, and 9.5 wt % of 1 M diethylzinc solution in heptane. According to the spectra, there was a blue shift from the expected bulk ZnSe emission indicating that the average diameter of the synthesized nanowires was below the quantum confinement threshold of 9 nm, as confirmed also by the TEM analysis. In addition, curve (2) is slightly blue shifted when compared to curve (1). This can be attributed to a slight decrease in the diameter of the cylindrical nanodomains in the second sample that lead to the formation of nanowires with smaller diameters.

### Example 5

### Synthesis of Nanodiscs

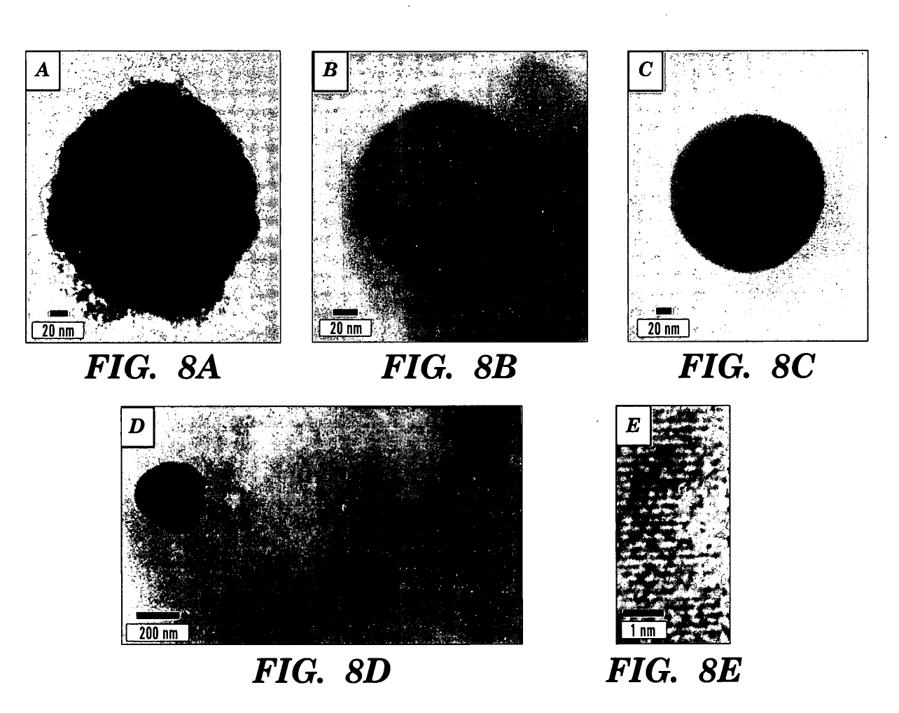

TEM images of ZnSe nanodiscs synthesized using different lamellar liquid crystal compositions are shown in FIGS. 8A-E. FIG. 8A corresponds to a template with a composition of 65 wt % EO₃₇PO₅₈EO₃₇, 25 wt % formamide, and 10 wt % of 1 M diethylzinc solution in heptane. FIG. 8B corresponds to a template with a composition of 69 wt % EO₃₇PO₅₈EO₃₇, 20 wt % formamide, and 11 wt % of 1 M diethylzinc solution in heptane. FIGS. 8C and 8D correspond to a template with a composition of 72 wt % EO₃₇PO₅₈EO₃₇, 19 wt % formamide, and 9 wt % of 1 M diethylzinc solution in heptane. Using these liquid templates, the production of the nanostructures was completed as described above. As indicated by the TEM images, the thickness and roundness of the produced nanodiscs depended on the composition of the liquid crystal template used. Minimization of the total free energy, which is achieved through minimization of the number of unsaturated surface bonds, causes the edges of the synthesized planar structures to attain a disc-like shape. The average thickness of the nanodiscs was estimated to be in the order of the non-polar lamella thickness (i.e. approximately 6 nm (Svensson et al., “Self-Assembly of a Poly(Ethylene Oxide)/Poly(Propylene Oxide) Block Copolymer (Pluronic P 104, (EO)₂₇(PO)₆₁(EO)₂₇) in the Presence of Water and Xylene,” J. Phys. Chem. B 102(39):7541-7548 (1998), which is hereby incorporated by reference in its entirety)). FIG. 8E shows an HR-TEM image of a nanodisc synthesized in a template composed of 65 wt % EO₃₇PO₅₈EO₃₇, 22 wt % formamide, and 13 wt % of 1 M diethylzinc solution in heptane. The crystalline quality of the synthesized nanodiscs is evident from this image.

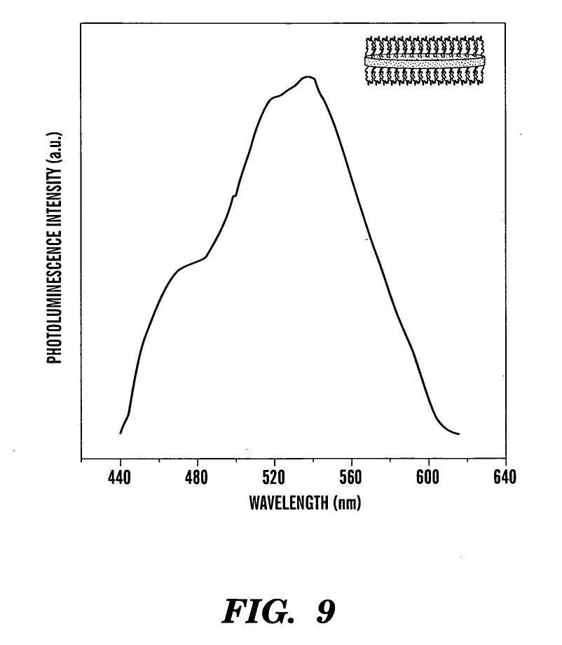

The ZnSe nanodiscs are luminescent at room temperature and their photoluminescence is red-shifted compared to bulk ZnSe (460 nm). The PL spectrum in FIG. 9 corresponds to a lamellar liquid crystal composition of 72 wt % EO₃₇PO₅₈EO₃₇, 19 wt % formamide, and 9 wt % of 1 M diethylzinc solution in heptane. The red-shift was probably caused by the presence of Se vacancies or by self-activated luminescence due to donor-acceptor pairs related to Zn vacancies and interstitial states, which might be present on the surface of the nanocrystals, as has been previously reported for synthesis of various ZnSe nanostructures (Li et al., “Preparation and Optical Properties of Sol-Gel Derived ZnSe Crystallites Doped in Glass Fil,” J. Appl. Phys. 75(8):4276-4278 (1994); Li et al., “Control Synthesis of Semiconductor ZnSe Quasi-Nanospheres by Reverse Micelles Soft Template,” Mater. Lett. 59(13):1623-1626 (2005), each of which are hereby incorporated by reference in their entirety).

Techniques of the present invention enable control of the size and shape of compound semiconductor nanostructures using liquid crystal templates formed by self-assembly of a PEO-PPO-PEO amphiphilic block copolymer in the presence of heptane and formamide. ZnSe quantum dots, nanowires, and nanodiscs have been grown inside the spherical, cylindrical, and planar nanodomains of the cubic, hexagonal, and lamellar liquid crystalline phases of the above ternary system, respectively. The phase behavior of the ternary system at room temperature was investigated in order to delineate the compositions corresponding to the phases of interest. The technique employs reactions between a group-II alkyl (diethylzinc) and a group-VI hydride (hydrogen selenide), similar to those used by the microelectronics industry for epitaxial growth of thin films. Hydrogen selenide gas that is brought into contact with the templates diffuses into the liquid crystals and reacts with diethylzinc to form ZnSe clusters inside the heptane nanodomains. The ZnSe clusters coalesce to form a crystalline nanostructure in each nanodomain. This approach has produced for the first time ZnSe nanowires with diameters smaller than 10 nm, as well as self-standing disc-like quantum wells. By selecting the templating phase and by tuning the size of the heptane nanodomains and the concentration of the metal alkyl in them, the shape and size of the nanostructures grown in the self-assembled nanodomains can be manipulated.

Although preferred embodiments have been depicted and described in detail herein, it will be apparent to those skilled in the relevant art that various modifications, additions, substitutions, and the like can be made without departing from the spirit of the invention and these are therefore considered to be within the scope of the invention as defined in the claims which follow.

What is claimed:

1. A process for synthesizing nanostructures, said process comprising:
providing a first reactant;
forming a liquid crystalline template containing the first reactant;
contacting a gas phase comprising a second reactant diluted in a carrier gas with the liquid crystalline template; and
allowing the second reactant to react with the first reactant; under conditions effective to form nanostructures.

2. The process according to claim 1, wherein the first reactant comprises a metal-containing compound.

3. The process according to claim 2, wherein the metal comprises Zn, Cd, Hg, or Pb.

4. The process according to claim 1, wherein the first reactant comprises an organometallic compound.

5. The process according to claim 4, wherein the organometallic compound comprises dimethyl-Zn, dimethyl-Cd, dimethyl-Hg, diethyl-Zn, diethyl-Cd, diethyl-Hg, tetramethyl-Pb, or tetraethyl-Pb.

6. The process according to claim 5, wherein the organometallic compound is diethyl-Zn.

7. The process according to claim 5, wherein the organometallic compound is dimethyl-Zn.

8. The process according to claim 5, wherein the organometallic compound is diethyl-Cd.

9. The process according to claim 5, wherein the organometallic compound is dimethyl-Cd.

10. The process according to claim 1, wherein said forming of a liquid crystalline template comprises:
providing a block copolymer;
providing a polar continuous phase material;
providing a dispersed nonpolar phase material; and
allowing the block copolymer, polar continuous phase material, and dispersed nonpolar phase material to come into contact with each other;
under conditions effective to form said liquid crystalline template.

11. The process according to claim 10, wherein the block copolymer is comprised of poly (ethylene oxide) and poly (propylene oxide).

12. The process according the claim 10, wherein the polar continuous phase material is a non-reactive polar solvent.

13. The process according the claim 10, wherein the polar continuous phase material is formamide.

14. The process according to claim 10, wherein the dispersed nonpolar phase material is an organic solvent.

15. The process according to claim 14, wherein said organic solvent is an alkane.

16. The process according to claim 15, wherein said alkane is heptane.

17. The process according to claim 1, wherein said second reactant is in the form of a gas or vapor.

18. The process according to claim 1, wherein said second reactant comprises a Group VI element-containing compound.

19. The process according to claim 18, wherein said Group VI element comprises Se, S, Te, or O.

20. The process according to claim 18, wherein said Group VI element-containing compound is in the form of a hydride.

21. The process according to claim 20, wherein said hydride is a hydride of Se, S, or Te.

22. The process according to claim 21, wherein said hydride of Se is H₂Se gas.

23. The process according to claim 19, wherein said Group VI element is oxygen.

24. The process according to claim 23, wherein the oxygen-containing compound is in the form of molecular oxygen (O₂) gas, ozone (O₃) gas, or water (H₂0) vapor.

25. The process according to claim 19, wherein said Group VI element is Te.

26. The process according to claim 25, wherein the Te-containing compound is in the form of a vapor of dimethyl-Te, diethyl-Te, or diisopropyl-Te.

27. The process according to claim 1, wherein said carrier gas comprises hydrogen, nitrogen, helium, or argon.

28. The process according to claim 1, wherein said contacting comprises bubbling said gas phase over said liquid crystalline template under conditions effective to allow said second reactant to diffuse into said template and to react with said first reactant to form said nanostructures.

29. The process according to claim 1, wherein said contacting is performed at a temperature at which said liquid crystalline template remains stable at atmospheric pressure or at a pressure higher than atmospheric pressure.

30. The process according to claim 1, wherein said nanostructures have a diameter of between about 1 and about 100 nanometers.

31. The process according to claim 1, wherein said nanostructures are in crystalline form, polycrystalline form, or amorphous form.

32. The process according to claim 1, wherein said nanostructures are nanocrystals.

33. The process according to claim 32, wherein said nanocrystals exhibit size-dependent luminescence or fluorescence.

34. The process according to claim 32, wherein said nanocrystals are PbSe or PbS nanocrystals.

35. The process according to claim 32, wherein said nanocrystals are luminescent Group II-Group VI nanocrystals of the form MX, wherein M is Zn, Cd, or Hg, and wherein X is Se, S, Te, or O.

36. The process according to claim 35, wherein said nanocrystals are ZnSe nanocrystals.

37. The process according to claim 36, wherein said ZnSe nanocrystals have a diameter of between about 1.0 and about 200 nanometers.

38. The process according to claim 35, wherein said nanocrystals are CdSe nanocrystals.

39. The process according to claim 38, wherein said CdSe nanocrystals have a diameter of between about 1.0 and about 200 nanometers.

40. The process according to claim 1 further comprising incorporating a functional material onto the surface of said nanostructures.

41. The process according to claim 40, wherein said functional material is dissolved in an aliphatic hydrocarbon.

42. The process according to claim 41, wherein said aliphatic hydrocarbon is heptane.

43. The process according to claim 41, wherein said aliphatic hydrocarbon is octane.

44. The process according to claim 40, wherein said functional material is dissolved in an aromatic hydrocarbon.

45. The process according to claim 44, wherein said aromatic hydrocarbon is p-xylene.

46. The process according to claim 44, wherein said aromatic hydrocarbon is toluene.

47. The process according to claim 40, wherein said functional material is dissolved in heptane.

48. The process according to claim 40, wherein said functional material is added to the outer surface of said nanostructure.

49. The process according to claim 40, wherein said functional material comprises either a thiol-based compound or an amine-based compound.

50. The process according to claim 1 further comprising isolating said nanostructures.

51. The process according to claim 1, wherein said nanostructures are of substantially the same size.

52. The process according to claim 51, wherein the size of said nanostructures is dependent on the initial concentration of the first reactant prior to said contacting.

53. A liquid crystalline template produced by the process comprising:
providing a block copolymer;
providing a polar continuous phase material;
providing a dispersed nonpolar phase material; and
allowing the block copolymer, polar continuous phase material, and dispersed nonpolar phase material to come into contact with each other;
under conditions effective to form said liquid crystalline template.

54. The process according to claim 53, wherein the block copolymer is comprised of poly (ethylene oxide) and poly (propylene oxide).

55. The process according to claim 53, wherein the polar continuous phase material is a non-reactive polar solvent.

56. The process according the claim 53, wherein the polar continuous phase material is formamide.

57. The process according to claim 53, wherein the dispersed nonpolar phase material is an organic solvent.

58. The process according to claim 57, wherein said organic solvent is an alkane.

59. The process according to claim 58, wherein said alkane is heptane.
